(19) United States
(12) Patent Application Publication
(10) Pub. No.: US 2023/0138887 A1
(43) Pub. Date: May 4, 2023

(54) SEMICONDUCTOR LIGHT-EMITTING ELEMENT COLLECTING METHOD AND SEMICONDUCTOR LIGHT-EMITTING ELEMENT COLLECTING METHOD USING SAME

(71) Applicant: LG ELECTRONICS INC., Seoul (KR)

(72) Inventors: Dohwan YANG, Seoul (KR); Dohee KIM, Seoul (KR); Yongil SHIN, Seoul (KR)

(73) Assignee: LG ELECTRONICS INC., Seoul (KR)

(21) Appl. No.: 17/793,896

(22) PCT Filed: Feb. 3, 2020
(86) PCT No.: PCT/KR2020/001558

§ 371 Date: Jul. 19, 2022

(30) Foreign Application Priority Data
Jan. 20, 2020 (KR) 10-2020-0007461

(51) Int. Cl. H01L 25/075; H01L 33/00

(52) U.S. Cl. CPC H01L 25/0753; H01L 33/005

(57) ABSTRACT

According to a semiconductor light-emitting element collecting apparatus and a semiconductor light-emitting element collecting method using the same according to an embodiment of the present invention, in order to collect semiconductor light-emitting elements, a fluid accommodated in a housing unit is rotated such that semiconductor light-emitting elements are guided to sink to a bottom surface of the housing unit, and accordingly, the semiconductor light-emitting elements can be rapidly collected. In addition, a collecting operation can be performed without exerting the physical force to the semiconductor light-emitting elements, a collecting rate of the semiconductor light-emitting elements can be improved.

### TECHNICAL FIELD

The present disclosure relates to a semiconductor light-emitting element collecting apparatus for collecting semiconductor light-emitting elements remaining after assembly in manufacturing a display device using the to semiconductor light-emitting elements, and a method for collecting semiconductor light-emitting elements using the same.

### BACKGROUND ART

In recent years, in the field of display technology, liquid-crystal displays (LCDs), organic light-emitting diodes (OLED) displays, microLED displays, etc. have been competing to realize large-area displays.

Semiconductor light-emitting diodes (microLEDs) with a diameter or cross-sectional area less than 100 μm, when used in displays, may offer very high efficiency because the displays do not need a polarizer to absorb light. However, large-scale displays require several millions of semiconductor light-emitting diodes, which makes it difficult to transfer the devices compared to other technologies.

Some of the technologies currently in development for the transfer process include pick & place, laser lift-off (LLO), and self-assembly. Among these technologies, the self-assembly approach is a method that allows semiconductor light-emitting diodes to find their positions on their own in a fluid, which is most advantageous in realizing large-screen display devices.

Self-assembly methods may include a method of directly assembling a semiconductor light-emitting element on a final substrate to be used in a product, and a method of assembling a semiconductor light-emitting element on an assembly substrate and transferring the semiconductor light-emitting element to a final substrate through an additional transfer process. The direct assembly method on the final substrate is efficient in terms of process, and the method using the assembly substrate is advantageous in terms of additionally using a structure for self-assembly without limitation. Therefore, the two methods are selectively used.

### DISCLOSURE OF INVENTION

### Technical Problem

The present disclosure describes a semiconductor light-emitting element collecting apparatus capable of rapidly collecting semiconductor light-emitting elements remaining in a fluid after self-assembly, and a method for collecting semiconductor light-emitting elements using the same.

The present disclosure also describes a semiconductor light-emitting element collecting apparatus capable of collecting semiconductor light-emitting elements without damage, and a method for collecting semiconductor light-emitting elements using the same.

### Solution to Problem

A semiconductor light-emitting element collecting apparatus according to an implementation disclosed herein may include a housing unit configured to accommodate a fluid and semiconductor light-emitting elements, a rotation generation unit configured to rotate the fluid accommodated in the housing unit, and a fluid removal unit configured remove the fluid accommodated in the housing unit. The semiconductor light-emitting elements settled on a bottom surface of the housing unit may be collected by rotation of the fluid accommodated in the housing unit.

In an implementation, the housing unit may include an opening formed through at least an opposite side of the bottom surface.

In an implementation, the housing unit may be formed to be tapered in width from the opening to the bottom surface.

In an implementation, the rotation generation unit may rotate the fluid accommodated in the housing unit centering on a symmetry axis of the housing unit.

In an implementation, the rotation generation unit may rotate the fluid accommodated in the housing unit while moving from edge to center of the housing unit.

A method for collecting semiconductor light-emitting elements according to an implementation may include (a) feeding a fluid and semiconductor light-emitting elements to a housing unit, (b) rotating the fluid accommodated in the housing unit so that the semiconductor light-emitting elements accommodated in the housing unit are settled on a bottom surface of the housing unit, (c) removing the fluid accommodated in the housing unit in a state where the semiconductor light-emitting elements accommodated in the housing unit are fully settled on the bottom surface of the housing unit, and (d) collecting the semiconductor light-emitting elements settled on the bottom surface of the housing unit.

In one implementation, the housing unit may include an opening formed through at least an opposite side of the bottom surface, and may be formed to be tapered in width from the opening to the bottom surface.

In one implementation, the step (b) may be carried out to rotate the fluid accommodated in the housing unit centering on a symmetry axis of the housing unit.

In one implementation, the step (b) may start at an edge of the housing unit and end at a center of the housing unit.

In one implementation, the steps (a) to (d) may be performed after the semiconductor light-emitting elements are seated on preset positions of a substrate within a chamber containing the fluid.

### Advantageous Effects of Invention

According to an implementation, semiconductor light-emitting elements remaining in a fluid after self-assembly can be quickly collected.

In addition, since the semiconductor light-emitting elements are collected without exerting a physical force, a collecting rate of the semiconductor light-emitting elements can be improved.

### BRIEF DESCRIPTION OF DRAWINGS

FIG. 1 is a conceptual view illustrating one implementation of a display device using semiconductor light-emitting elements.

FIG. 2 is a partial enlarged view of the portion A in the display device of FIG. 1.

FIG. 3 is an enlarged view of the semiconductor light-emitting element of FIG. 2.

FIG. 4 is an enlarged view illustrating another implementation of the semiconductor light-emitting element of FIG. 2.

FIGS. 5A to 5E are conceptual diagrams illustrating a new process for manufacturing the semiconductor light-emitting element.

FIG. 6 is a conceptual diagram illustrating an example of a device for self-assembling semiconductor light-emitting elements.

FIG. 7 is a block diagram of the self-assembly device of FIG. 6.

FIGS. 8A to 8E are conceptual view illustrating a process for self-assembling semiconductor light-emitting elements using the self-assembly device of FIG. 6.

FIG. 9 is a conceptual view illustrating the semiconductor light-emitting element of FIGS. 8A to 8E.

FIG. 10 is a conceptual view illustrating a semiconductor light-emitting element collecting apparatus in accordance with an implementation.

FIGS. 11A to 11E are conceptual views for explaining a process of collecting semiconductor light-emitting elements using a semiconductor light-emitting element collecting apparatus in accordance with an implementation.

### MODE FOR THE INVENTION

Description will now be given in detail according to exemplary implementations disclosed herein, with reference to the accompanying drawings. For the sake of brief description with reference to the drawings, the same or equivalent components may be provided with the same or similar reference numbers, and description thereof will not be repeated. In general, a suffix such as “module” and “unit” may be used to refer to elements or components. Use of such a suffix herein is merely intended to facilitate description of the specification, and the suffix itself is not intended to give any special meaning or function. In describing the present disclosure, if a detailed explanation for a related known function or construction is considered to unnecessarily divert the gist of the present disclosure, such explanation has been omitted but would be understood by those skilled in the art. The accompanying drawings are used to help easily understand the technical idea of the present disclosure and it should be understood that the idea of the present disclosure is not limited by the accompanying drawings. It will be understood that when an element such as a layer, area or substrate is referred to as being “on” another element, it can be directly on the element, or one or more intervening elements may also be present.

A display device disclosed herein may include a mobile phone, a smart phone, a laptop computer, a digital broadcast terminal, a personal digital assistant (PDA), a portable multimedia player (PMP), a navigator, a slate PC, a tablet PC, an ultrabook, a digital TV, a desktop computer, and the like. However, the configuration according to the implementation described herein can be applied as long as it can include a display even of it is a new product form to be developed later.

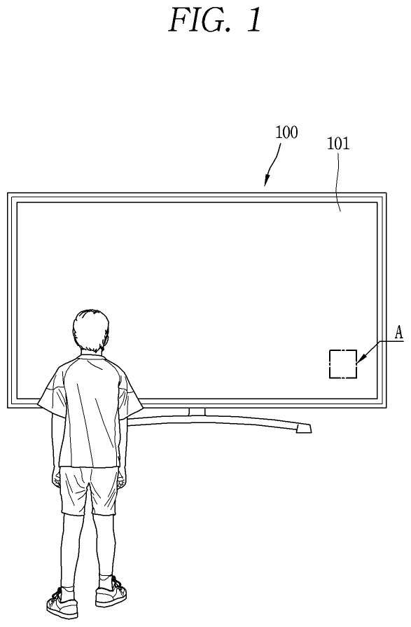

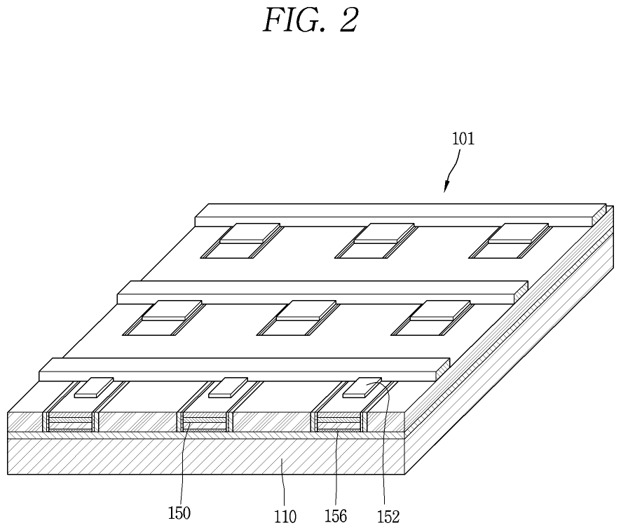

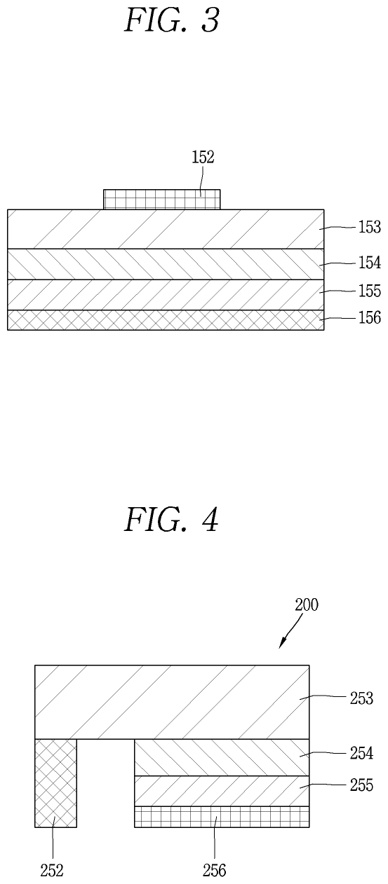

FIG. 1 is a conceptual view illustrating one implementation of a display device using semiconductor light-emitting elements, FIG. 2 is a partial enlarged view of the portion A in the display device of FIG. 1, FIG. 3 is an enlarged view of the semiconductor light-emitting element of FIG. 2, and FIG. 4 is an enlarged view illustrating another implementation of the semiconductor light-emitting element of FIG. 2.

As illustrated, information processed by a controller of a display device 100 may be output on a display module 140. A closed loop-shaped case 101 that runs around the edge of the display module 140 may define the bezel of the display device.

The display module 140 may include a panel 141 that displays an image, and the panel 141 may include micro-sized semiconductor light-emitting elements (or diodes) 150 and a wiring substrate 110 where the semiconductor light-emitting elements 150 are mounted.

The wiring substrate 110 may be provided with wirings, which can be connected to n-type electrodes 152 and p-type electrodes 156 of the semiconductor light-emitting elements 150. As such, the semiconductor light-emitting elements 150 may be provided on the wiring substrate 110 as individual pixels that emit light on their own.

The image displayed on the panel 141 may be visual information, which is rendered by controlling the light emission of unit pixels (sub-pixels) arranged in a matrix configuration independently through the wirings.

The present disclosure takes microLEDs (light-emitting diodes) as an example of the semiconductor light-emitting elements 150 which convert current into light. The microLEDs may be light-emitting elements that are small in size less than 100 micron meters. The semiconductor light-emitting elements 150 may have light-emitting regions of red, green, and blue, and unit pixels may be produced by combinations of these colors. That is, the unit pixels are the smallest units for producing one color. Each unit pixel may contain at least three microLEDs.

More specifically, referring to FIG. 3, the semiconductor light-emitting element 150 may have a vertical structure.

For example, the semiconductor light-emitting elements 150 may be implemented as high-power light-emitting elements that are composed mostly of gallium nitride (GaN), with some indium (In) and/or aluminum (Al) added to it, and emit light of various colors.

Such a vertical semiconductor light-emitting element may include a p-type electrode 156, a p-type semiconductor layer 155 disposed on the p-type semiconductor layer 156, an active layer 154 disposed on the p-type semiconductor layer 155, an n-type semiconductor layer 153 disposed on the active layer 154, and an n-type electrode 152 disposed on the n-type semiconductor layer 153. In this case, the p-type electrode 156 at the bottom may be electrically connected to a p-electrode of the wiring substrate, and the upper n-type electrode 152 at the top may be electrically connected to an n-electrode above the semiconductor light-emitting element. The electrodes can be disposed in an upward/downward direction in the vertical semiconductor light-emitting element 150, thereby providing a great advantage of reducing a chip size.

In another example, referring to FIG. 4, the semiconductor light-emitting elements may be flip chip-type light-emitting elements.

As an example of such a flip chip-type light-emitting element, the semiconductor light-emitting element 250 may include a p-type electrode 256, a p-type semiconductor layer 255 disposed on the p-type layer 256, an active layer 254 disposed on the p-type semiconductor layer 255, an n-type semiconductor layer 253 disposed on the active layer 254, and an n-type electrode 252 vertically separated from the p-type electrode 256 on the n-type semiconductor layer 253. In this case, both the p-type electrode 256 and the n-type electrode 252 may be electrically connected to a p electrode and an n electrode of the wiring substrate, below the semiconductor light-emitting element.

The vertical semiconductor light-emitting element and a horizontal light-emitting element each may be used as a green semiconductor light-emitting element, blue semiconductor light-emitting element, or red semiconductor light-emitting element. The green semiconductor light-emitting element and the blue semiconductor light-emitting element may be implemented as high-power light-emitting elements that are composed mostly of gallium nitride (GaN), with some indium (In) and/or aluminum (Al) added to it, and emit green and blue light, respectively. As an example, the semiconductor light-emitting elements may be made of gallium nitride thin films which include various layers of n-Gan, p-GaN, AlGaN, InGaN, etc. More specifically, the p-type semiconductor layer may be P-type GaN, and the n-type semiconductor layer may be N-type GaN. However, for the red semiconductor light-emitting element, the p-type semiconductor layer may be P-type GaAs, and the n-type semiconductor layer may be N-type GaAs.

Moreover, the p-type semiconductor layer may be P-type GaN doped with Mg on the p electrode, and the n-type semiconductor layer may be N-type GaN doped with Si on the n electrode. In this case, the above-described semiconductor light-emitting elements may be semiconductor light-emitting elements without the active layer.

In some examples, referring to FIGS. 1 to 4, because of the very small size of the light-emitting elements, self-emissive, high-definition unit pixels may be arranged on the display panel, and therefore the display device can deliver high picture quality.

In the display device using the semiconductor light-emitting elements, semiconductor light-emitting elements may be grown on a wafer, formed through mesa and isolation, and used as individual pixels. In this case, the micro-sized semiconductor light-emitting elements 150 should be transferred onto a wafer, at preset positions on a substrate of the display panel. One of the transfer technologies available may be pick and place, but it has a low success rate and requires a lot of time. In another example, a number of diodes may be transferred at a time by using a stamp or roll, which, however, is not suitable for large-screen displays because of limited yields. The present disclosure proposes a new method and device for manufacturing a display device that can solve these problems.

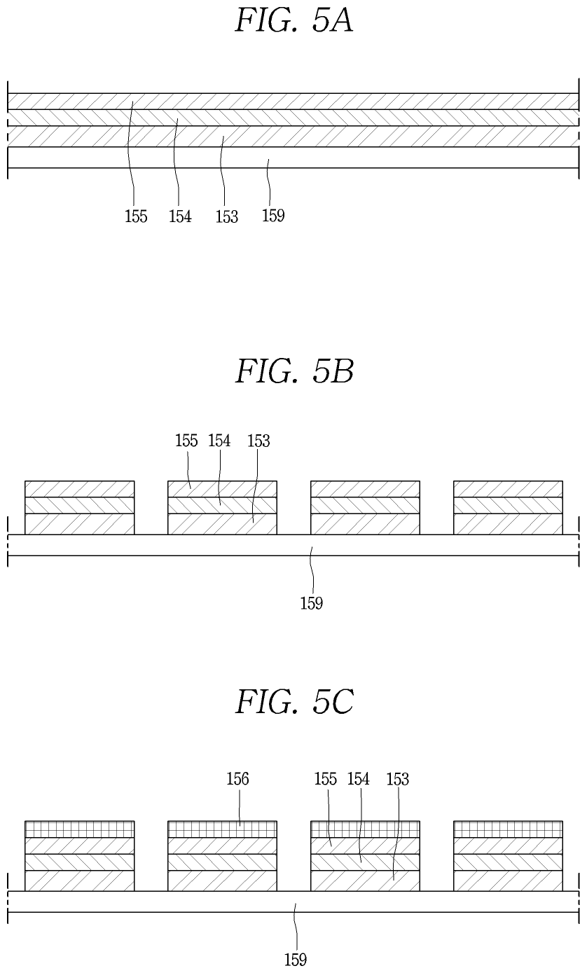

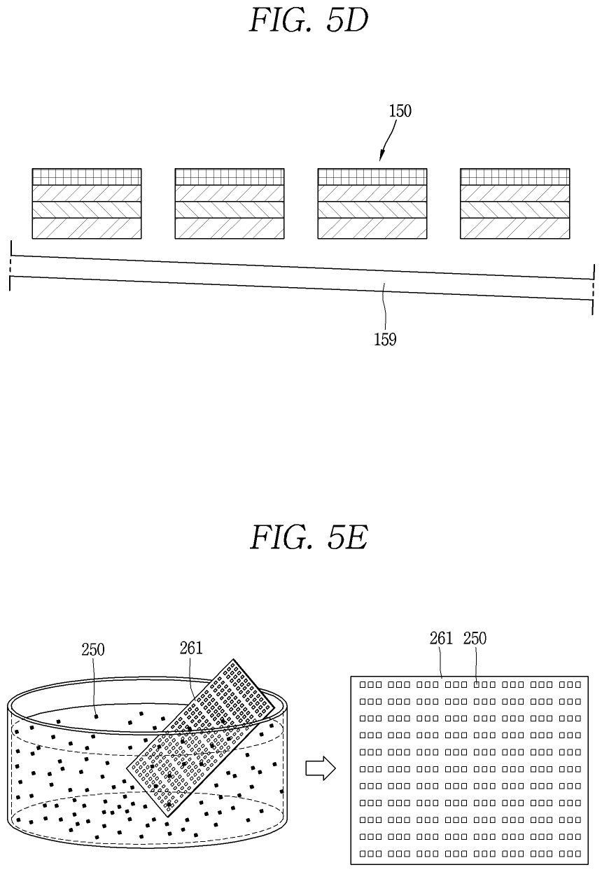

To this end, a new method for manufacturing a display device will be described first below. FIGS. 5A to 5E are conceptual views illustrating a new process for manufacturing the semiconductor light-emitting elements (or diodes).

In this specification, a display device using passive matrix (PM) type semiconductor light-emitting elements will be illustrated. However, an example described below may also be applicable to an active matrix (AM) type semiconductor light-emitting element. Also, although the illustration will be given of how horizontal semiconductor light-emitting elements are self-assembled, it may also be applied to self-assembling of vertical semiconductor light-emitting elements.

First of all, according to the manufacturing method, a first conductive semiconductor layer 153, an active layer 154, and a second conductive semiconductor layer 155 may be grown on a growth substrate 159 (FIG. 5A).

Once the first conductive semiconductor layer 153 is grown, the active layer 154 may be grown on the first conductive semiconductor layer 153 and then the second conductive semiconductor layer 155 may be grown on the active layer 154. By sequentially growing the first conductive semiconductor layer 153, the active layer 154, and the second conductive semiconductor layer 155, the first conductive semiconductor layer 153, the active layer 154, and the second conductive semiconductor layer 155 may form a stack structure as illustrated in FIG. 5A.

In this case, the first conductive semiconductor layer 153 may be a p-type semiconductor layer, and the second conductive semiconductor layer 155 may be an n-type semiconductor layer. However, the present disclosure is not necessarily limited to this, and the first conductive type may be n-type and the second conductive type may be p-type.

Moreover, although this exemplary implementation is illustrated by assuming the presence of the active layer, the active layer may be omitted if necessary, as stated above. In an example, the p-type semiconductor layer may be P-type GaN doped with Mg, and the n-type semiconductor layer may be N-type GaN doped with Si on the n electrode.

The growth substrate 159 (wafer) may be formed of, but not limited to, light-transmissive material, for example, one of sapphire (Al2O3), GaN, ZnO, and AlO. Also, the growth substrate 159 may be made of a material suitable for growing semiconductor materials, namely, a carrier wafer. The growth substrate 2101 may also be formed of a material having high thermal conductivity. The growth substrate 2101 may use at least one of a SiC substrate having higher thermal conductivity than the sapphire (Al2O3) substrate, Si, GaAs, GaP, InP and Ga2O3, in addition to a conductive substrate or an insulating substrate.

Next, a plurality of semiconductor light-emitting elements may be formed by removing at least parts of the first conductive semiconductor layer 153, the active layer 154, and the second conductive semiconductor layer 155 (FIG. 5B).

More specifically, isolation may be performed so that the plurality of light-emitting elements form a light-emitting diode array. That is, a plurality of semiconductor light-emitting elements may be formed by vertically etching the first conductive semiconductor layer 153, the active layer 154, and the second conductive semiconductor layer 155.

In the case of horizontal semiconductor light-emitting elements, a mesa process may be performed which exposes the first conductive semiconductor layer 153 to the outside by vertically removing part of the active layer 154 and the second conductive semiconductor layer 155, and then isolation may be performed which forms an array of semiconductor light-emitting elements by etching the first conductive semiconductor layer 153.

Next, a second conductive electrode 156 (or p-type electrode) may be formed on one surface of the second conductive semiconductor layer 155 (FIG. 5C). The second conductive electrode 156 may be formed by a deposition method such as sputtering, but the present disclosure is not necessarily limited to this. In a case where the first conductive semiconductor layer and the second conductive semiconductor layer are an n-type semiconductor layer and a p-type semiconductor layer, respectively, the second conductive electrode 156 may serve as an n-type electrode.

Next, the growth substrate 159 may be removed, thus leaving a plurality of semiconductor light-emitting elements. For example, the growth substrate 159 may be removed using laser lift-off (LLO) or chemical lift-off (CLO) (FIG. 5D).

Afterwards, the step of mounting the semiconductor light-emitting elements 150 on a substrate in a chamber filled with a fluid may be performed (FIG. 5E).

For example, the semiconductor light-emitting elements 150 and the substrate 161 may be put into a chamber filled with a fluid, and the to semiconductor light-emitting elements may be self-assembled onto the substrate 161 using fluidity, gravity, surface tension, etc. In this case, the substrate may be an assembly substrate 161.

In another example, a wiring substrate, instead of the assembly substrate 161, may be put into a fluid chamber, and the semiconductor light-emitting elements 150 may be mounted directly onto the wiring substrate. In this case, the substrate may be a wiring substrate. For convenience of explanation, the present disclosure is illustrated with an example in which the semiconductor light-emitting elements 150 are mounted onto the assembly substrate 161.

To facilitate the mounting of the semiconductor light-emitting elements 150 onto the assembly substrate 161, cells (not shown) into which the semiconductor light-emitting elements 150 are fitted may be provided on the assembly substrate 161. Specifically, cells where the semiconductor light-emitting elements 150 are mounted may be disposed on the assembly substrate 161 at positions where the semiconductor light-emitting elements 150 are aligned with wiring electrodes. The semiconductor light-emitting elements 150 may be assembled to the cells as they move within the fluid.

After arraying the semiconductor light-emitting elements 150 on the assembly substrate 161, the semiconductor light-emitting elements 150 may be transferred to the wiring substrate from the assembly substrate 161, thereby enabling a large-area transfer across a large area. Thus, the assembly substrate 161 may be referred to as a temporary substrate.

Meanwhile, the above-explained self-assembly method requires a higher transfer yield so that it can be applied to the manufacture of large-screen displays. The present disclosure proposes a method and device that minimizes the effects of gravity or friction and avoids non-specific binding, in order to increase the transfer yield.

In this case, in the display device according to the present disclosure, a magnetic material may be placed on the semiconductor light-emitting elements so that the semiconductor light-emitting elements are moved by magnetic force, and the semiconductor light-emitting elements may be mounted at preset positions by an electric field in the process of being moved. This transfer method and device will be described in more detail below with reference to the accompanying drawings.

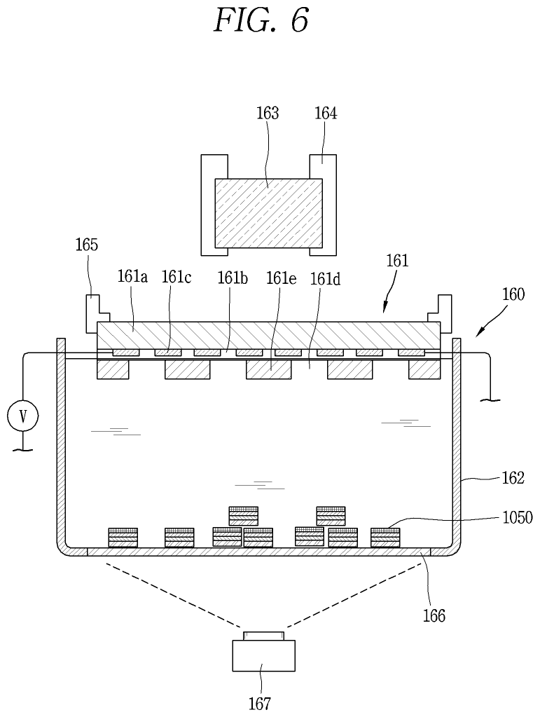

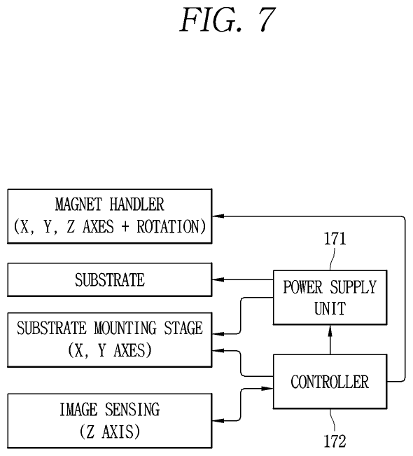

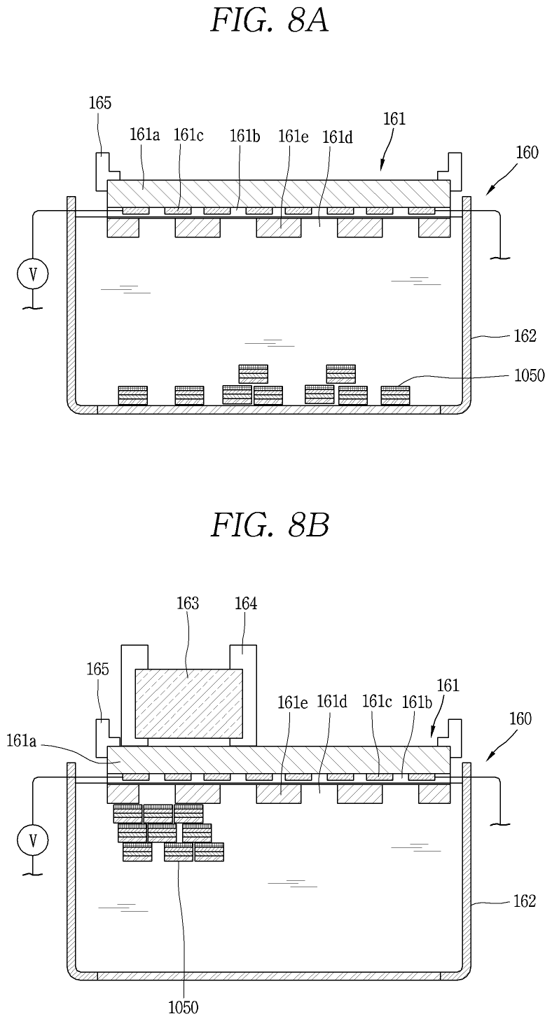

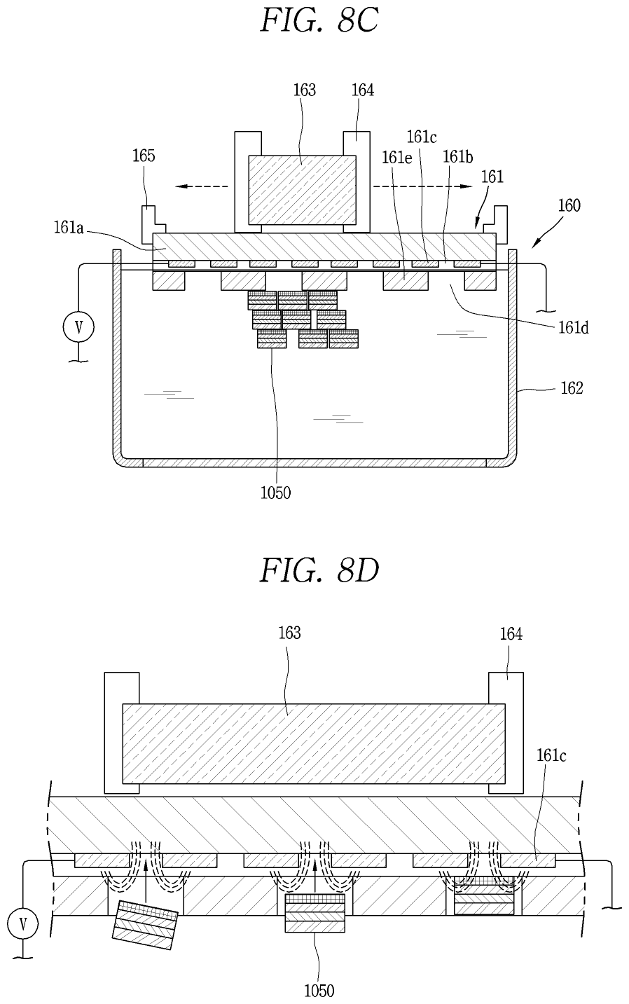

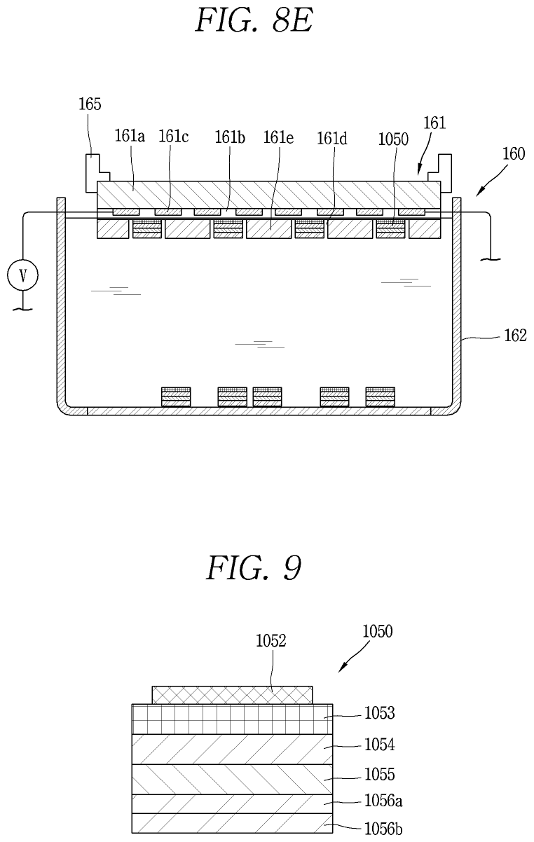

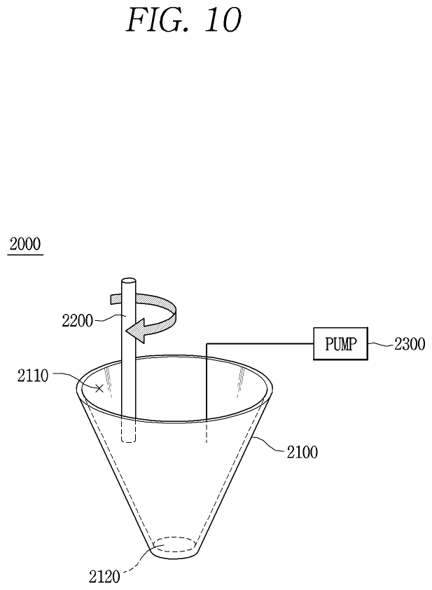

FIG. 6 is a conceptual diagram illustrating an example of a device for self-assembling semiconductor light-emitting elements and FIG. 7 is a block diagram of the self-assembly device of FIG. 6. FIGS. 8A to 8E are conceptual view illustrating a process for self-assembling semiconductor light-emitting elements using the self-assembly device of FIG. 6 and FIG. 9 is a conceptual view illustrating the semiconductor light-emitting element of FIGS. 8A to 8E.

Referring to FIGS. 6 and 7, the self-assembly device 160 may include a fluid chamber 162, a magnet 163, and a position controller 164.

The fluid chamber 162 may define a space for receiving a plurality of semiconductor light-emitting elements. The space may be filled with a fluid, and the fluid may be an assembly solution, which includes water or the like. Thus, the fluid chamber 162 may be a water tank and configured as an open-type. However, the present disclosure is not limited to this, and the fluid chamber 162 may be a closed-type chamber in which the space is in a closed state.

A substrate 161 may be placed in the fluid chamber 162 so that an assembly surface where the semiconductor light-emitting elements 150 are assembled faces downwards. For example, the substrate 161 may be fed to an assembly site by a feed unit (transfer unit), and the transfer unit may include a stage 165 where the substrate is mounted. The position of the stage 165 may be adjusted by the controller, whereby the substrate 161 can be fed to the assembly site.

In this instance, the assembly surface of the substrate 161 at the assembly site may face the bottom of the fluid chamber 162. As illustrated in the drawings, the assembly surface of the substrate 161 may be placed to be soaked with the fluid in the fluid chamber 162. Thus, the semiconductor light-emitting elements 150 in the fluid may be moved to the assembly surface.

The substrate 161 may be an assembly substrate where an electric field can be formed, and may include a base portion 161a, a dielectric layer 161b, and a plurality of electrodes 161c.

The base portion 161a may be made of an insulating material, and the plurality of electrodes 161c may be thin-film or thick-film bi-planar electrodes that are patterned on one surface of the base portion 161a. The electrodes 161c may be formed of a stack of Ti/Cu/Ti, Ag paste, ITO, etc.

The dielectric layer 161b may be made of an inorganic material such as SiO2, SiNx, SiON, Al2O3, TiO2, HfO2, etc. Alternatively, the dielectric layer 161b may be an organic insulator and configured as a single layer or multi-layers. The thickness of the dielectric layer 161b may range from several tens of nm to several μm.

Further, the substrate 161 according to the present disclosure may include a plurality of cells 161d that are separated by barrier walls 161e. The cells 161d may be sequentially arranged in one direction and made of polymer material. Also, the barrier walls 161e defining the cells 161d may be shared by neighboring cells 161d. The barrier walls 161e may protrude from the base portion 161a, and the cells 161d may be sequentially arranged in one direction along the barrier walls 161e. More specifically, the cells 161d may be sequentially arranged in column and row directions and have a matrix configuration.

As illustrated in the drawings, the cells 161d may have recesses for receiving the semiconductor light-emitting elements 150, and the recesses may be spaces defined by the barrier walls 161e. The recesses may have a shape identical or similar to the shape of the semiconductor light-emitting elements. For example, if the semiconductor light-emitting elements are rectangular, the recesses may be rectangular too. Moreover, although not shown, the recesses formed in the cells may be circular if the semiconductor light-emitting diodes are circular. Further, each cell may be configured to receive one semiconductor light-emitting element. That is, one cell may receive one semiconductor light-emitting element.

Meanwhile, the plurality of electrodes 161c may have a plurality of electrode lines that are placed at the bottom of the cells 161d, and the electrode lines may extend to neighboring cells.

The plurality of electrodes 161c may be placed beneath the cells 161d, and different polarities may be applied to create an electric field within the cells 161d. To form an electric field, the dielectric layer 161b may form the bottom of the cells 161d while covering the electrodes 161c. With this structure, when different polarities are applied to a pair of electrodes 161c beneath each cell 161d, an electric field may be formed and the semiconductor light-emitting elements can be inserted into the cells 161d by the electric field.

The electrodes of the substrate 161 at the assembly site may be electrically connected to a power supply 171. The power supply 171 may perform the function of generating the electric field by applying power to the electrodes.

As shown in the drawings, the self-assembly device may have the magnet 163 for applying magnetic force to the semiconductor light-emitting elements. The magnet 163 may be disposed at a distance from the fluid chamber 162 to apply magnetic force to the semiconductor light-emitting elements 150. The magnet 163 may be disposed to face an opposite side of the assembly surface of the substrate 161, and the position of the magnet 163 may be controlled by the position controller 164 connected to the magnet 163.

The semiconductor light-emitting elements 1050 may have a magnetic material so that they can be moved within the fluid by a magnetic field.

Referring to FIG. 9, a semiconductor light-emitting element having a magnetic material may include a first conductive electrode 1052, a second conductive electrode 1056, a first conductive semiconductor layer 1053 on which the first conductive electrode 1052 is disposed, a second conductive semiconductor layer 1055 which overlaps the first conductive semiconductor layer 1052 and on which the second conductive electrode 1056 is disposed, and an active layer 1054 disposed between the first and second conductive s semiconductor layers 1053 and 1055.

Here, the first conductive may refer to p-type, and the second conductive type may refer to n-type, or vice versa. As stated previously, the semiconductor light-emitting diode may be formed without the active layer.

Meanwhile, the first conductive electrode 1052 may be formed after the semiconductor light-emitting element is assembled onto the wiring substrate by the self-assembling of the semiconductor light-emitting element. Further, the second conductive electrode 1056 may include a magnetic material. The magnetic material may refer a magnetic metal. The magnetic material may be Ni, SmCo, etc. In another example, the magnetic material may include at least one of Gd-based, La-based, and Mn-based materials.

The magnetic material may be provided in the form of particles on the second conductive electrode 1056. Alternatively, one layer of a conductive electrode including a magnetic material may be made of the magnetic material. As an example, the second conductive electrode 1056 of the semiconductor light-emitting element 1050 may include a first layer 1056a and a second layer 1056b, as illustrated in FIG. 9. Here, the first layer 1056a may include a magnetic material, and the second layer 1056b may include a metal material other than the magnetic material.

As illustrated in the drawing, in this example, the first layer 1056a including the magnetic material may be disposed in contact with the second conductive semiconductor layer 1055. In this case, the first layer 1056a may be disposed between the second layer 1056b and the second conductive semiconductor layer 1055. The second layer 1056b may be a contact metal that is connected to the second electrode on the wiring substrate. However, the present disclosure is not necessarily limited to this, and the magnetic material may be disposed on one surface of the first conductive semiconductor layer.

Still referring to FIGS. 6 and 7, more specifically, on top of the fluid chamber of the self-assembly device, a magnet handler capable of automatically or manually moving the magnet 163 on the x, y, and z axes or a motor capable of rotating the magnet 163 may be provided. The magnet handler and motor may constitute the position controller 164. As such, the magnet 163 may rotate in a horizontal, clockwise, or counterclockwise direction with respect to the substrate 161.

Meanwhile, the fluid chamber 162 may be provided with a light-transmissive bottom plate 166, and the semiconductor light-emitting elements may be disposed between the bottom plate 166 and the substrate 161. An image sensor 167 may be disposed to face the bottom plate 166 so as to monitor the inside of the fluid chamber 162 through the bottom plate 166. The image sensor 167 may be controlled by a controller 172, and may include an inverted-type lens, CCD, etc. so as to observe the assembly surface of the substrate 161.

The self-assembly device may be configured to use a magnetic field and an electric field in combination. With this, the semiconductor light-emitting elements can be mounted at preset positions on the substrate by the electric field while being moved by changes in the position of the magnet. Hereinafter, the assembly process using the self-assembly device will be described in more detail.

First of all, a plurality of semiconductor light-emitting elements 1050 having a magnetic material may be formed through the process explained with reference to FIGS. 5A to 5C. In this case, the magnetic material may be deposited onto the semiconductor light-emitting elements in the process of forming the second conductive electrode of FIG. 5C.

Next, the substrate 161 may be fed to an assembly site, and the semiconductor light-emitting elements 1050 may be put into the fluid chamber 162 (FIG. 8A).

As described above, the assembly site on the substrate 161 may be a position at which the substrate 161 is placed in the fluid chamber 162 in such a way that an assembly surface where the semiconductor light-emitting elements 150 are assembled faces downwards.

In this case, some of the semiconductor light-emitting elements 1050 may sink to the bottom of the fluid chamber 162 and some of them may float in the fluid. When the fluid chamber 162 is provided with the light-transmissive bottom plate 166, some of the semiconductor light-emitting elements 1050 may sink to the bottom plate 166.

Next, magnetic force may be applied to the semiconductor light-emitting elements 1050 so that the semiconductor light-emitting elements 1050 in the fluid chamber 162 come up to the surface (FIG. 8B).

When the magnet 163 of the self-assembly device moves to the opposite side of the assembly surface of the substrate 161 from its original position, the semiconductor light-emitting elements 1050 may float in the fluid towards the substrate 161. The original position may refer to s position at which the magnet 163 is outside the fluid chamber 162. As another example, the magnet 163 may be configured as an electromagnet. In this case, an initial magnetic force may be generated by supplying electricity to the electromagnet.

Meanwhile, in this implementation, the spacing between the assembly surface of the substrate 161 and the semiconductor light-emitting elements 1050 may be controlled by adjusting strength of the magnetic force. For example, the spacing may be controlled by using weight, buoyancy, and magnetic force of the semiconductor light-emitting elements 1050. The spacing may be several millimeters to several tens of micrometers from the outermost part of the substrate 161.

Next, magnetic force may be applied to the semiconductor light-emitting elements 1050 so that the semiconductor light-emitting elements 1050 can move in one direction within the fluid chamber 162. For example, the magnet 163 may move in a horizontal direction to the substrate, a clockwise direction, or a counterclockwise direction (FIG. 8C). In this case, the semiconductor light-emitting elements 1050 may be moved horizontally with respect to the substrate 161 by the magnetic force, with being spaced apart from the substrate 161.

Next, the semiconductor light-emitting elements 1050 may be guided to preset positions on the substrate 161 by applying an electric field so that the semiconductor light-emitting elements 1050 are mounted at the preset positions during their movement (FIG. 8C). For example, the semiconductor light-emitting elements 1050 may be moved vertically with respect to the substrate 161 by the electric field while being moved horizontally with respect to the substrate 161, thereby being placed at the preset positions of the substrate 161.

More specifically, an electric field may be generated by supplying power to bi-planar electrodes on the substrate 161, and the semiconductor light-emitting electrodes 1050 may be guided to be assembled only at the preset positions by the electric field. That is, the semiconductor light-emitting elements 1050 may be self-assembled at the assembly site on the substrate 161 by a selectively generated electric field. To this end, the substrate 161 may be provided with cells into which the semiconductor light-emitting elements 1050 are fitted.

Afterwards, unloading of the substrate 161 may be performed, thereby completing the assembly process. In a case where the substrate 161 is an assembly substrate, the assembled semiconductor light-emitting elements may be transferred onto a wiring substrate to carry out a subsequent process for realizing the display device, as described previously.

Meanwhile, after the semiconductor light-emitting elements 1050 are guided to the preset positions, the magnet 163 may be moved away from the substrate 161 such that the semiconductor light-emitting elements 1050 remaining in the fluid chamber 162 fall to the bottom of the fluid chamber 162 (FIG. 8D). In another example, when power supply is stopped in a case where the magnet 163 is an electromagnet, the semiconductor light-emitting elements 1050 remaining in the fluid chamber 162 may fall to the bottom of the fluid chamber 162.

Thereafter, the semiconductor light-emitting elements 1050 on the bottom of the fluid chamber 162 may be collected, and the collected semiconductor light-emitting elements 1050 may be re-used.

In the above-explained self-assembly device and method, parts at far distances may be concentrated near a preset assembly site by using a magnetic field in order to increase assembly yields in a fluidic assembly, and guided to be selectively assembled only at the assembly site by applying an electric field to the assembly site. In this case, the assembly substrate may be positioned on top of a water tank, with its assembly surface facing downward, thereby minimizing the effect of gravity from the weights of the parts and avoiding non-specific binding and eliminating defects. That is, the assembly substrate may be placed on the top to increase transfer yields, thus minimizing the effect of gravity or friction and avoiding non-specific binding.

As seen from above, with the configuration, a large number of semiconductor light-emitting elements can be assembled at a time in a display device where individual pixels are made up of semiconductor light-emitting elements.

As such, a large number of semiconductor light-emitting elements can be pixelated on a small-sized wafer and then transferred onto a large-area substrate. This enables the manufacture of a large-area display device at a low cost.

Hereinafter, a semiconductor light-emitting element collecting apparatus and a method for collecting semiconductor light-emitting elements using the same according to implementations will be described with reference to the accompanying drawings.

First, a semiconductor light-emitting element collecting apparatus 2000 disclosed herein will be described with reference to FIG. 10.

FIG. 10 is a conceptual view illustrating a semiconductor light-emitting element collecting apparatus in accordance with an implementation.

The semiconductor light-emitting element collecting apparatus 2000 according to an implementation may be provided for efficiently collecting semiconductor light-emitting elements dispersed in a fluid.

For example, the semiconductor light-emitting element collecting apparatus 2000 may be used to collect the semiconductor light-emitting elements 1050 remaining in a fluid chamber 162 after the self-assembly according to FIGS. 8A to 8E is completed.

The self-assembly method according to FIGS. 8A to 8E may be a method for assembling the semiconductor light-emitting elements 1050 having a size of several to several tens of μm to the substrate 161. This method may be carried out after dispersing the semiconductor light-emitting elements 1050 that are much more than (at least 30 to 100 times of) the semiconductor light-emitting elements 1050 which are actually assembled to the substrate 161. Therefore, when self-assembly is completed, a process of collecting the semiconductor light-emitting elements 1050 that are not assembled on the substrate 161 should be carried out.

In the related art, the semiconductor light-emitting elements 1050 remaining in the fluid after completion of self-assembly were manually collected using a dedicated pipette.

However, since it took a considerable time to collect, there was a limit in collecting substantially all of the remaining semiconductor light-emitting elements 1050. In addition, a significant number of semiconductor light-emitting elements 1050 were damaged by the pipette.

A semiconductor light-emitting element collecting apparatus 2000 according to an implementation of the present disclosure may solve the problem of the related art manual collecting method.

According to the implementation disclosed herein, the semiconductor light-emitting element collecting apparatus 2000 may include a housing unit 2100, a rotation generation unit 2200, and a fluid removal unit 2300.

A fluid and semiconductor light-emitting elements 4000 may be accommodated in the housing unit 2100.

The housing unit 2100 may include an opening 2110 to accommodate the fluid and the semiconductor light-emitting elements 4000. For example, the housing unit 2100 may include the opening 2110 through at least an opposite side of a bottom surface 2120. Alternatively, the housing unit 2100 may include first and second openings formed through the bottom surface 2120 and an opposite side of the bottom surface 2120, and may further include a separate cover for covering the first opening of the bottom surface 2120 during collection.

The housing unit 2100 may be formed to be tapered in width from the opening 2110 to the bottom surface 2120. Such a shape may allow the semiconductor light-emitting elements 4000 to be accommodated in the housing unit 2100 as many as possible through the opening 2110 while allowing the semiconductor light-emitting elements 400 to be intensively collected onto a region of the relatively narrow bottom surface 2120.

The rotation generation unit 2200 may rotate the fluid accommodated in the housing unit 2100.

The rotation generation unit 2200 may rotate the fluid accommodated in the housing unit 2100 centering on a symmetry axis c of the housing unit 2100. Accordingly, a vortex may be generated by the rotation generation unit 2200 in the fluid accommodated in the housing unit 2100. In response to this, the semiconductor light-emitting elements 4000 dispersed in the fluid may also rotate together with the fluid centering on the symmetry axis c of the housing unit 2100.

Also, the rotation generation unit 2200 may rotate the fluid accommodated in the housing unit 2100 while moving from edge to center of the housing unit 2100. During this process, the semiconductor light-emitting elements 4000 dispersed in the housing unit 2100 may be concentrated in the central portion of the housing unit 2100, and further may be settled (sunk) on the bottom surface 2120 of the housing unit 2100 due to the weight of the semiconductor light-emitting elements 4000.

According to an implementation, for the rotation generation unit 2200, any apparatus and method for generating power may be used without limitation, and various variables (direction, speed, etc.) related to rotation may also be arbitrarily determined within an appropriate range.

The fluid removal unit 2300 may remove the fluid contained in the housing unit 2100. For example, a pump may be provided as the fluid removal unit 2300.

The fluid removal unit 2300 may be disposed to remove the fluid contained in the housing unit 2100 so that the semiconductor light-emitting elements 4000 settled on the bottom surface 2120 can be easily collected.

Preferably, the fluid removal unit 2300 may remove the fluid contained in the housing unit 2100 after the semiconductor light-emitting elements 4000 in the housing unit 2100 are fully settled.

For this, a configuration for scanning the inside of the housing unit 2100 may be separately provided. In this case, the housing unit 2100 may be formed of a light-transmitting transparent material.

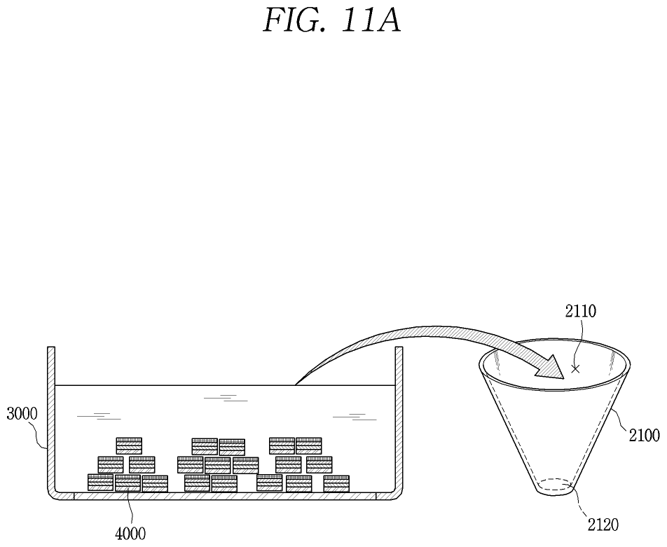

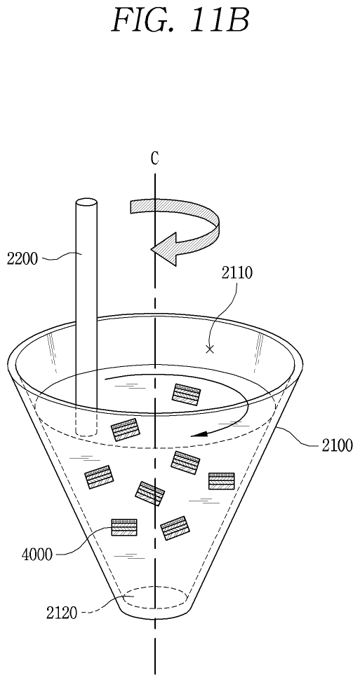

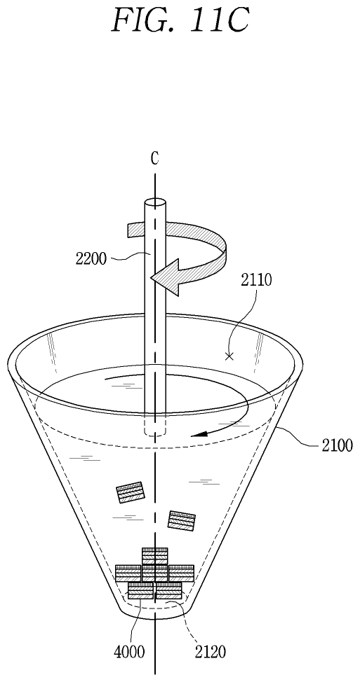

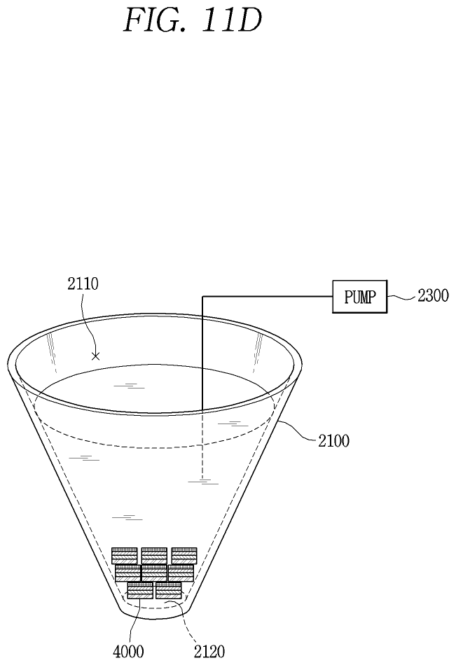

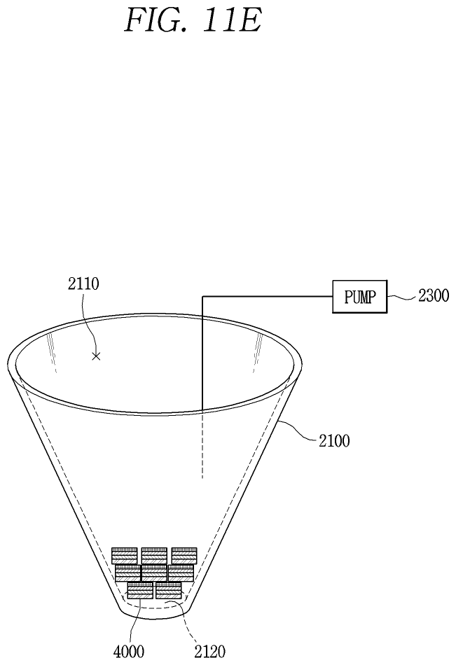

Hereinafter, a method for collecting semiconductor light-emitting elements using the semiconductor light-emitting element collecting apparatus 2000 will be described with reference to FIGS. 11A to 11E.

FIGS. 11A to 11E are conceptual views for explaining a process of collecting semiconductor light-emitting elements using a semiconductor light-emitting element collecting apparatus in accordance with an implementation.

The semiconductor light-emitting element collecting method according to an implementation may be performed after the semiconductor light-emitting elements 1050 are seated on preset positions of the substrate 161 in the fluid chamber 162 as illustrated in FIGS. 8A to 8E, and may proceed in the following sequence.

First, a step (a) of feeding the fluid and the semiconductor light-emitting elements 4000 into the housing unit 2100 may be performed (FIG. 11A). The fluid fed to the housing unit 2100 may be the fluid contained in the fluid chamber 3000 in which the self-assembly has been performed, and the semiconductor light-emitting elements 4000 may be those left in the fluid chamber 3000 without being assembled to the substrate after the completion of the self-assembly.

The housing unit 2100 may include the opening 2110 at least through an opposite side of the bottom surface 2120. The fluid and the semiconductor light-emitting elements 4000 may be accommodated in the housing unit 2100 through the opening 2110. Meanwhile, the semiconductor light-emitting elements 4000 may be collectively collected by being settled on the bottom surface 2120.

Also, the housing unit 2100 may be formed to be tapered in width from the opening 2110 to the bottom surface 2120. This may allow the semiconductor light-emitting elements 4000 to be accommodated in the housing unit 2100 as many as possible through the opening 2110 while allowing the semiconductor light-emitting elements 400 to be intensively collected onto a region of the relatively narrow bottom surface 2120.

Next, a step (b) of rotating the fluid contained in the housing unit 2100 so that the semiconductor light-emitting elements 4000 accommodated in the housing unit 2100 are settled on the bottom surface of the housing unit 2100 may be performed (FIG. 11B). For example, the step (b) may be performed by the rotation generation unit 2200 as illustrated in FIG. 11B.

The step (b) may be configured to rotate the fluid accommodated in the housing unit 2100 centering on a symmetry axis c of the housing unit 2100. During this process, the semiconductor light-emitting elements 4000 dispersed in the fluid may be concentrated in the vicinity of the symmetry axis c while rotating centering on the symmetry axis c.

Also, the step (b) may start at the edge of the housing unit 2100 and end at the center of the housing unit 2100 (FIG. 11C). The central portion may be on the symmetry axis c or in the vicinity of the symmetry axis c.

In addition, while the step (b) is carried out, various variables (direction, speed, etc.) related to rotation may also be arbitrarily determined within an appropriate range.

The semiconductor light-emitting elements 4000 may gradually be settled on the bottom surface of the housing unit 2100 as the step (b) proceeds.

Next, a step (c) of removing the fluid contained in the housing unit 2100 may be performed. The step (c) may be performed by the fluid removal unit 2300, for example, by a pump provided as the fluid removal unit 2300.

Also, preferably, the step (c) may be performed in a state where the semiconductor light-emitting elements 4000 accommodated in the housing unit 2100 are all settled on the bottom surface 2120 of the housing unit 2100 (FIG. 11D).

Finally, a step (d) of collecting the semiconductor light-emitting elements 4000 settled on the bottom surface 2120 of the housing unit 2100 may be performed. The step (d) may be performed after the fluid is removed in the state where the semiconductor light-emitting elements 4000 are settled on the bottom surface 2120 as illustrated in FIG. 11E, and the collecting method may not be limited thereto.

As described above, according to the implementation, the semiconductor light-emitting elements 4000 remaining in the fluid after self-assembly can be rapidly collected, and also the collection of the semiconductor light-emitting elements 4000 can be performed without applying a physical force. This can provide an effect of improving a collection rate of the semiconductor light-emitting elements 4000.

It should be understood that the present disclosure is not limited to the configuration and method of the implementations described above but part or all of the implementations are selectively combined so that various modifications can be made.

1. A semiconductor light-emitting element collecting apparatus, comprising:
housing configured to accommodate a fluid and semiconductor light-emitting elements therein;
a rotation generator configured to rotate the fluid accommodated in the housing; and
a fluid remover configured to remove the fluid accommodated in the housing,
wherein the semiconductor light-emitting elements are settled on a bottom surface of the housing by a rotation of the fluid accommodated in the housing.

2. The semiconductor light-emitting element collecting apparatus of claim 1, wherein the housing comprises an opening formed in at least an opposite side to the bottom surface of the housing.

3. The semiconductor light-emitting element collecting apparatus of claim 2, wherein the housing is tapered in width from the opening to the bottom surface.

4. The semiconductor light-emitting element collecting apparatus of claim 1, wherein the rotation generator rotates the fluid accommodated in the housing centering on a symmetry axis of the housing.

5. The semiconductor light-emitting element collecting apparatus of claim 1, wherein the rotation generator rotates the fluid accommodated in the housing while moving from an edge to a center of the housing.

6. A method for collecting semiconductor light-emitting elements, the method comprising:
feeding a fluid and semiconductor light-emitting elements to housing;
rotating the fluid accommodated in the housing so that the semiconductor light-emitting elements accommodated in the housing are settled on a bottom surface of the housing;
removing the fluid accommodated in the housing in a state where the semiconductor light-emitting elements accommodated in the housing are settled on the bottom surface of the housing; and
collecting the semiconductor light-emitting elements settled on the bottom surface of the housing.

7. The method of claim 6, wherein the housing comprises an opening in at least an opposite side to the bottom surface of the housing, and is tapered in width from the opening to the bottom surface.

8. The method of claim 6, wherein the rotating is carried out to rotate the fluid accommodated in the housing centering on a symmetry axis of the housing.

9. The method of claim 6, wherein the rotating starts at an edge of the housing and ends at a center of the housing.

10. The method of claim 6, wherein the feeding, the rotating, the removing and the collecting are performed after some of the semiconductor light-emitting elements are seated on preset positions of a substrate within a chamber containing the fluid.

11. The method of claim 6, wherein the removing of the fluid is performed by a fluid remover.

12. The method of claim 6, wherein the housing is transparent.

13. The semiconductor light-emitting element collecting apparatus of claim 3, wherein a size of the opening is greater than a size of the bottom surface.

14. The semiconductor light-emitting element collecting apparatus of claim 1, wherein the housing is transparent.

15. The semiconductor light-emitting element collecting apparatus of claim 1, wherein the fluid remover is a pump.

16. A collecting apparatus for semiconductor light-emitting elements, the collecting apparatus comprising:
a housing configured to collect semiconductor light-emitting elements therein, and configured to accommodate a fluid and the semiconductor light-emitting elements suspended in the fluid; and
a rotation generator to control rotation of the fluid accommodated in the housing to enable the semiconductor light-emitting elements to settle at a bottom surface of the housing.

17. The collecting apparatus of claim 16, wherein an arc of rotation of the rotation generator is decreased from an inside edge of the housing towards a center of the housing to enable the semiconductor light-emitting elements to settle at the bottom surface of the housing when the rotation generator is rotating at the center.

18. The collecting apparatus of claim 16, further comprising a fluid remover to remove the fluid accommodated in the housing after the semiconductor light-emitting elements settle at the bottom surface of the housing.

19. The collecting apparatus of claim 16, wherein the housing comprises an opening formed at an opposite side to the bottom surface of the housing, and wherein a size of the opening is greater than a size of the bottom surface.

20. The collecting apparatus of claim 16, wherein the housing is transparent.
